(19) United States
(12) Patent Application Publication
(10) Pub. No.: US 2007/0045812 A1
(43) Pub. Date: Mar. 1, 2007

(54) Microfeature assemblies including interconnect structures and methods for forming such interconnect structures

(75) Inventor: Puah Kia Heng, Singapore (SG)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/217,712

(22) Filed: Aug. 31, 2005

(51) Int. Cl. H01L 23/48

(52) U.S. Cl. 257/693

(57) ABSTRACT

Microfeature assemblies including interconnect structures and methods for forming such interconnect structures are disclosed herein. One particular embodiment of a microfeature assembly includes a microelectronic die having integrated circuitry, a plurality of terminals electrically coupled to the integrated circuitry, and conductive bumps on the individual terminals. The conductive bumps include first engagement features. The assembly also includes a microfeature workpiece having a substrate and a plurality of pads on the substrate. The pads include non-planar second engagement features engaged with the first engagement features on corresponding conductive bumps.

### TECHNICAL FIELD

The present invention is directed generally toward microfeature assemblies including interconnect structures and methods for forming such interconnect structures. More particularly, several aspects of the present invention are related to interconnect structures for use in flip chip assemblies.

### BACKGROUND

Semiconductor devices and other types of microelectronic devices can include a microelectronic die attached to a ceramic chip carrier, organic printed circuit board, lead frame, or other type of interposing structure. The dies can be attached to interposing structures using Direct Chip Attach (DCA), flip-chip bonding, or wire-bonding to electrically connect the integrated circuitry in the dies to the wiring of the interposing structures. In typical DCA or flip-chip methods, for example, very small bumps or balls of a conductive material (e.g., solder) are deposited onto the contacts of a die. The bumps are then connected to corresponding contacts or pads on an interposing structure.

FIG. 1 is a side cross-sectional view illustrating a portion of a conventional assembly 10 including a microelectronic die 20 attached to an interposing structure 30. The die 20 includes a plurality of stud bumps 22 (only one is shown) in contact with a plurality of corresponding pads 32 (only one is shown) on the interposing structure 30. The stud bump 22 can include a base portion 23 and a stem portion 24. The base portion 23 is in electrical contact with a terminal or contact (not shown) on the die 20 and the stem portion 24 is positioned to contact the pad 32 to complete the interconnection. In the illustrated example, the stem portion 24 and the pad 32 are bonded together using an adhesive material 40 (e.g., a conductive or non-conductive adhesive). In alternative embodiments, the stud bump 22 and pad 32 could be bonded using other suitable methods (e.g., ultrasonic assembly without adhesive.)

One concern with forming the interconnection between the die 20 and the interposing structure 30 in FIG. 1 is that the surfaces of the die and/or interposing structure are not uniformly flat (i.e., the surfaces include a number of irregularities). Height variations between the contacts on the die 20 and the interposing structure 30 can (a) cause an uneven distribution of forces in the packaged device, (b) generate die fractures, and/or (c) cause an open connection in the packaged device that can cause an electrical short in the device. One approach to addressing this problem is “coining” or flattening the stud bumps 22 on the die 20 to provide a generally uniform surface for interconnection with corresponding pads 32. The stem portion 24 of the stud bump 22 illustrated in FIG. 1, for example, has been coined to provide a flatter end surface for more surface contact with the pad 32.

Although coining the end surfaces of the stud bumps 22 on the die 20 can help provide a more uniform surface for interconnection with the pads 32 on the interposing structure 30, interconnect structures with coined stud bumps 22 can include a number of drawbacks. For example, one problem with the interconnect structure illustrated in FIG. 1 is that the adhesive material 40 can require an extremely long in-process cure time to allow the adhesive to sufficiently cure such that it is able to withstand the various forces that will be exerted on the assembly 10 or resulting packaged device (e.g., mechanical and thermal forces). The long cure time can significantly decrease throughput of the packaged devices.

Another problem is that shear stresses (as shown by the arrow S) along the interface between the stud bump 22 and the pad 32 can cause delamination and/or failure of the joint. This problem is exacerbated during reliability stress testing of the assembly 10 (e.g., Autoclave and thermal cycling). For example, reliability testing processes can include heating the assembly 10 to extremely high temperatures and/or exposing the assembly 10 to extremely humid conditions. These conditions cause the various components of the die 20 and/or interposing structure 30 to expand and/or contract, which can in turn cause delamination along the interface between the stud bump 22 and the pad 32. Such delamination can result in open connections and electrical shorts in the assembly 10 or resulting packaged device. Accordingly, there is a need to improve the interconnect structures used in packaging microfeature assemblies.

### BRIEF DESCRIPTION OF THE DRAWINGS

FIG. 1 is a side cross-sectional view of a portion of a microfeature assembly including an interconnect structure in accordance with one aspect of the prior art.

FIG. 2 is a side cross-sectional view illustrating a portion of a microfeature assembly having a plurality of interconnect structures configured in accordance with an embodiment of the invention.

FIGS. 3A-3E are side cross-sectional views illustrating various stages in a method of forming pads having engagement features on a microfeature workpiece in accordance with an embodiment of the invention.

FIGS. 4A and 4B are side cross-sectional views of interconnect structures configured in accordance with additional embodiments of the invention.

FIGS. 4C-4E are top plan views of pads having engagement features configured in accordance with still further embodiments of the invention.

FIGS. 5A-5E are side cross-sectional views illustrating various stages in a method of forming pads having engagement features on a microfeature workpiece in accordance with another embodiment of the invention.

FIG. 5F is a side cross-sectional view of a packaged microfeature device including the pads formed in FIGS. 5A-5E in accordance with an embodiment of the invention.

### DETAILED DESCRIPTION

A. Overview/Summary

The present invention is directed toward microfeature assemblies including interconnect structures and methods for forming such interconnect structures. One particular embodiment of such a microfeature assembly includes a microelectronic die having integrated circuitry, a plurality of terminals electrically coupled to the integrated circuitry, and conductive bumps on the individual terminals. The conductive bumps include first engagement features. The assembly also includes a microfeature workpiece having a substrate and a plurality of pads on the substrate. The pads include non-planar second engagement features engaged with the first engagement features on corresponding conductive bumps.

The first and second engagement features are interlocking elements that restrict relative movement between the die and the workpiece. The first and second engagement features can have a number of different configurations. For example, the first engagement features can include protrusions or projections and the non-planar second engagement features can include recesses, a plurality of recesses, elongated trenches, a plurality of trenches, and/or recesses including outlet trenches.

Another aspect of the invention is directed to a packaged microfeature device. The device can include a microelectronic die having integrated circuitry and a plurality of bond-pads electrically coupled to the integrated circuitry. The device also includes a plurality of uncoined stud bumps on the bond-pads. The stud bumps can include base portions and stem portions projecting from the base portions. The stem portions of the stud bumps define first interconnecting features. The device can further include an interposer substrate having a plurality of pads. The pads can include non-planar second interconnecting features mated with corresponding first interconnecting features. The device can also include an adhesive material between the die and the interposing structure.

Still another aspect of the invention is directed to a method for forming a microfeature assembly. The method includes forming a plurality of pads having non-planar first engagement features on and/or in a microfeature workpiece. The method also includes attaching a plurality of conductive bumps on a microelectronic die to corresponding pads on the workpiece. The die includes integrated circuitry, a plurality of terminals electrically coupled to the integrated circuitry, and the conductive bumps on the terminals. The conductive bumps include second engagement features that mate with the first engagement features on the pads.

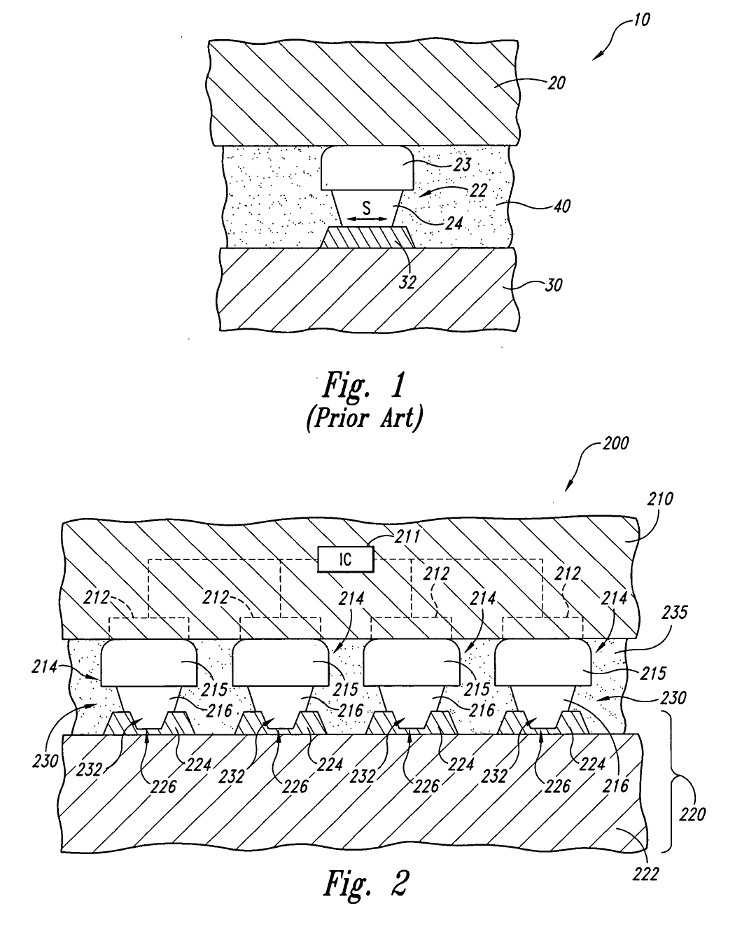

The term “microfeature workpiece” is used throughout to include substrates upon which and/or in which microelectronic circuits or components, data storage elements or layers, vias or conductive lines, micro-optic features, micromechanical features, and/or microbiological features are or can be fabricated using microlithographic techniques. The term “microfeature assembly” is used throughout to include a variety of articles of manufacture, including, e.g., semiconductor wafers having active components, individual integrated circuit dies, packaged dies, and subassemblies comprising two or more microelectronic workpieces or components, e.g., a stacked die package. Many specific details of certain embodiments of the invention are set forth in the following description and in FIGS. 2-5F to provide a thorough understanding of these embodiments. A person skilled in the art, however, will understand that the invention may be practiced without several of these details or additional details can be added to the invention. Well-known structures and functions have not been shown or described in detail to avoid unnecessarily obscuring the description of the embodiments of the invention. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same feature and/or additional types of features are not precluded.

B. Embodiments of Microfeature Assemblies Including Interconnect Structures Having Interlocking Elements

FIG. 2 is a side cross-sectional view illustrating a portion of a microfeature assembly 200 including a microelectronic die 210 coupled to a microfeature workpiece 220 in a flip-chip (FCIP) configuration with a plurality of interconnect structures 230. The interconnect structures 230 include interlocking elements 232 that substantially reduce or inhibit relative movement between the die 210 and the workpiece 220. Compared to the conventional stud bump interconnects described above with respect to the FIG. 1, the interconnect structures 230 are expected to (a) reduce delamination and/or failure of the interconnect structures 230, (b) increase the total contact area of the mechanical/electrical connection between the die 210 and the workpiece 220 as compared with conventional interconnects, and (c) reduce total processing time by decreasing the time required for in-process adhesive curing.

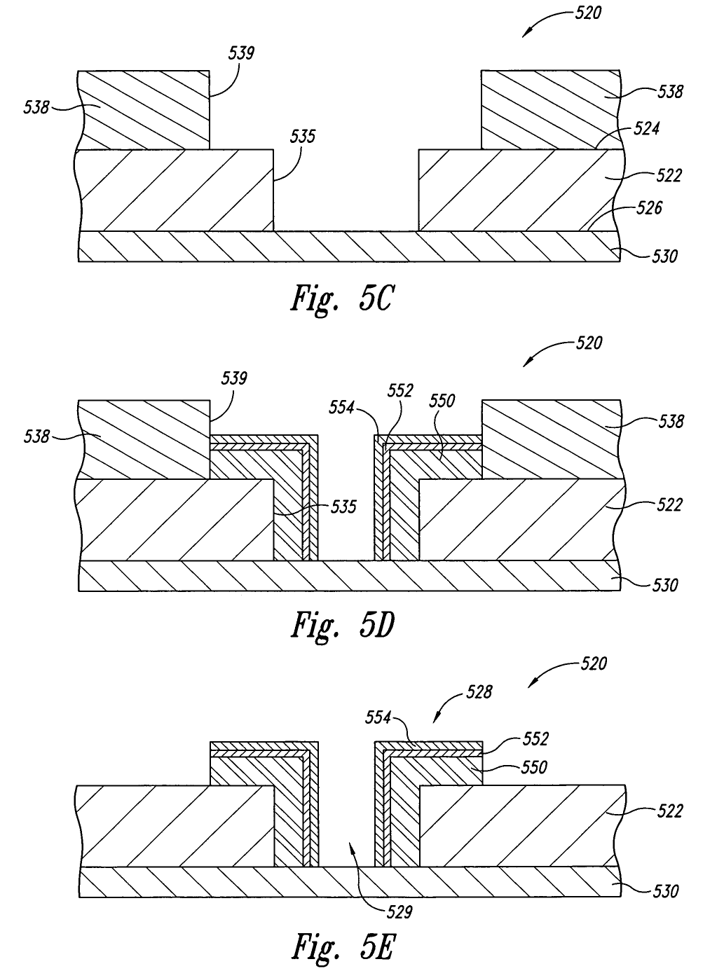

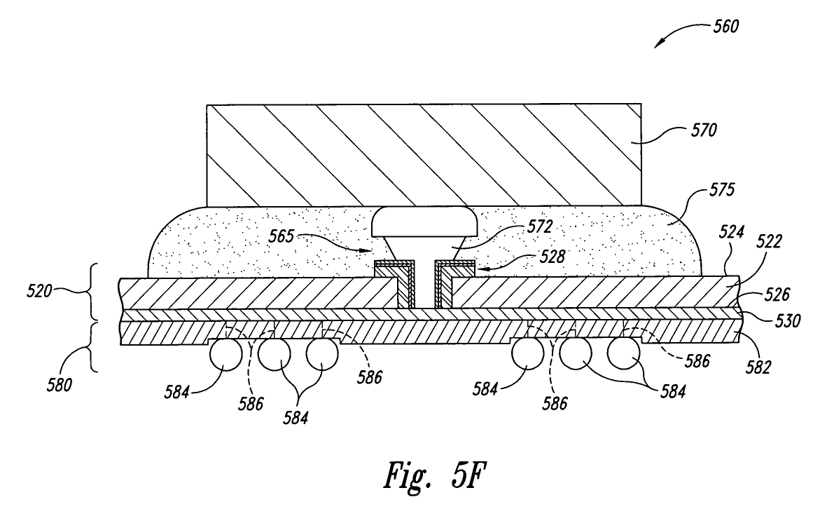

The workpiece 220 in the illustrated embodiment can include a substrate 222 having a plurality of pads 224 formed on and/or in the substrate 222. The substrate 222 can be a generally rigid material or a flexible material (as described below with respect to FIGS. 5A-5F). The individual pads 224 on the substrate 222 can be electrically coupled to an array of substrate contacts (not shown) at an opposite side of the substrate 222. The substrate contacts (not shown) are arranged in an array for surface mounting the assembly 200 to a board or module of another device. As such, the substrate 222 distributes signals from very small contacts on the die 210 to the larger array of substrate contacts at the opposite side of the substrate 222.

The die 210 can include integrated circuitry 211 (shown schematically), a plurality of terminals 212 (shown in broken lines) electrically coupled to the integrated circuitry 211, and a plurality of conductive bumps or stud bumps 214 projecting from corresponding terminals 212. The stud bumps 214 are “uncoined” stud bumps that can include base portions 215 and stem portions 216 projecting from the base portions 215. As discussed in greater detail below, the stem portions 216 of the stud bumps 214 are configured to engage corresponding engagement features in the pads 224 to form the interlocking elements 232 of the interconnect structures 230 that electrically and physically couple the die 210 to the workpiece 220.

In several embodiments, the stud bumps 214 can be formed with a wire bonding tool (not shown) and a modified wire bonding process. For example, the wire bonding tool can press a gold or gold alloy wire onto the terminals 212 under predetermined conditions of force and temperature to form the base portions 215 (e.g., gold balls) on the terminals 212. Thereafter, the wire bonding tool is pulled away from the die 210 and the wire is trimmed off close to the individual base portions 215, thereby forming the individual stem portions 216. In other embodiments, other methods can be used to form the stud bumps 214 and/or the stud bumps 214 can be formed from different materials.

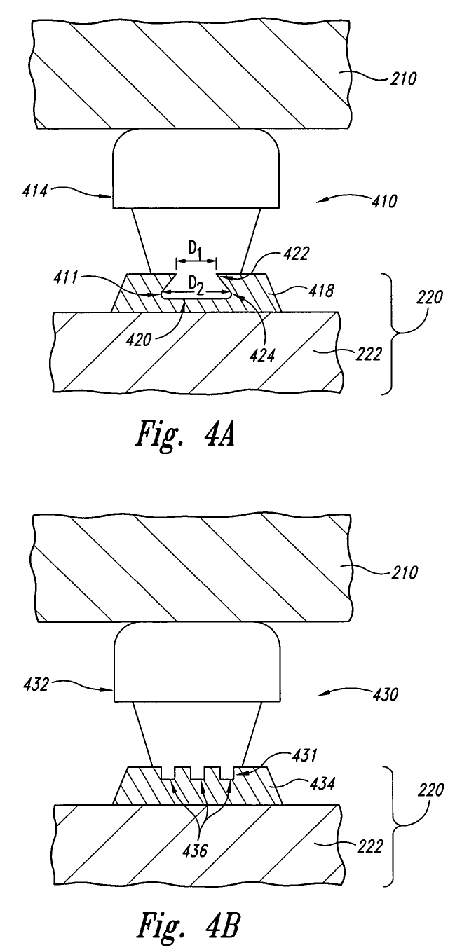

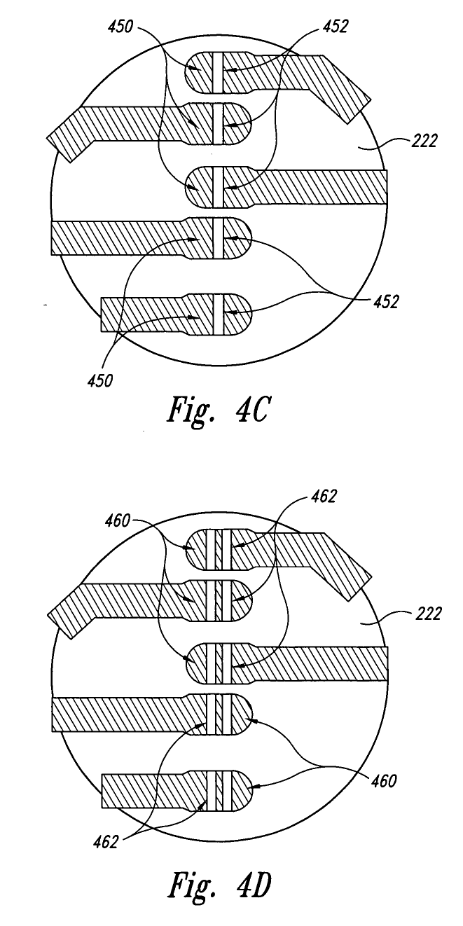

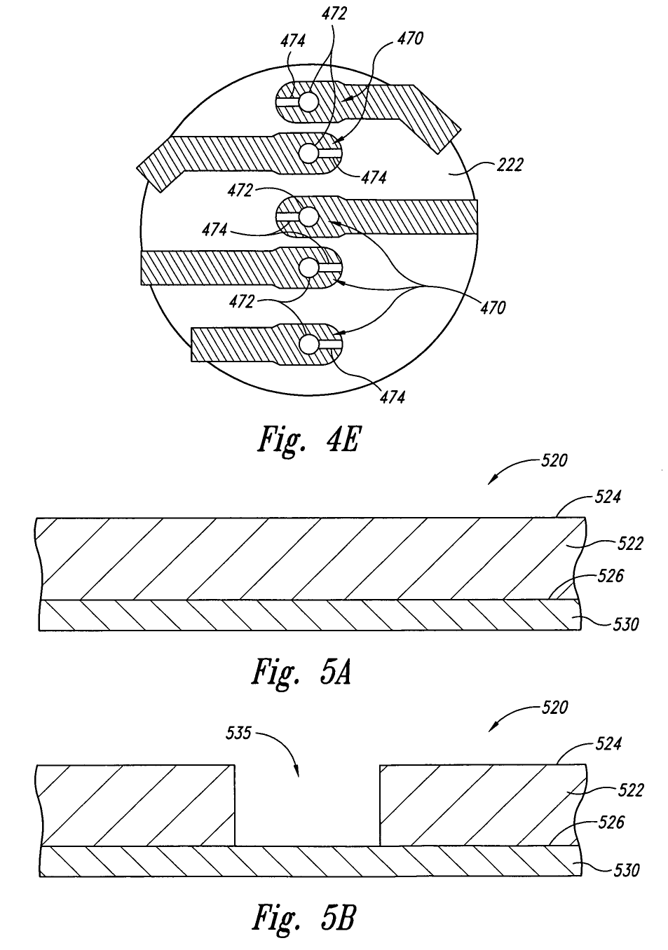

The pads 224 on the substrate 222 can include recesses or trenches 226 (i.e., non-planar features) that define engagement features or interlocking elements positioned to engage or otherwise mate with corresponding stud bumps 214 and inhibit relative movement between the die 210 and the workpiece 220. In the embodiment illustrated in FIG. 2, for example, the stem portions 216 of the individual stud bumps 214 are projections received in corresponding recesses 226 in the pads 224. In other embodiments described below with respect to FIGS. 4A-4E, the engagement features in the pads 224 and/or the stud bumps 214 can have different configurations.

In several embodiments, the assembly 200 can further include an adhesive or underfill material 235 disposed between the die 210 and the substrate 222 to help attach the die 210 to the substrate 222 and to protect the interconnect structures 230 from contamination (e.g., moisture, particulates, etc.). The adhesive material 235 can include an anisotropic conductive film, a non-conductive paste, or other suitable materials.

One feature of the interconnect structures 230 shown in FIG. 2 is that the stem portions 216 engage corresponding recesses 226 in the pads 224 to restrict movement between stud bumps 214 and the pads 224 that can occur during reliability stress testing, solder reflow processes, bake-in, and other thermal cycling events. The interconnect structures 230, more specifically, provide a mechanical interlock that prevents shear forces along the joints between the stud bumps 214 and the pads 224 from causing relative movement between the die 210 and the workpiece 220. Without the interlocking elements 232 of the interconnect structures 230, such movement can cause delamination between the stud bumps 214 and the pads 224.

The interlocking elements 232 of the interconnect structures 230 also increase the total contact surface area between the stud bumps 214 and the pads 224. This feature can further increase the adhesion between the stud bumps 214 and the corresponding pads 224, as well as increasing the electrical contact between the contacts on the die 210 and the workpiece 220.

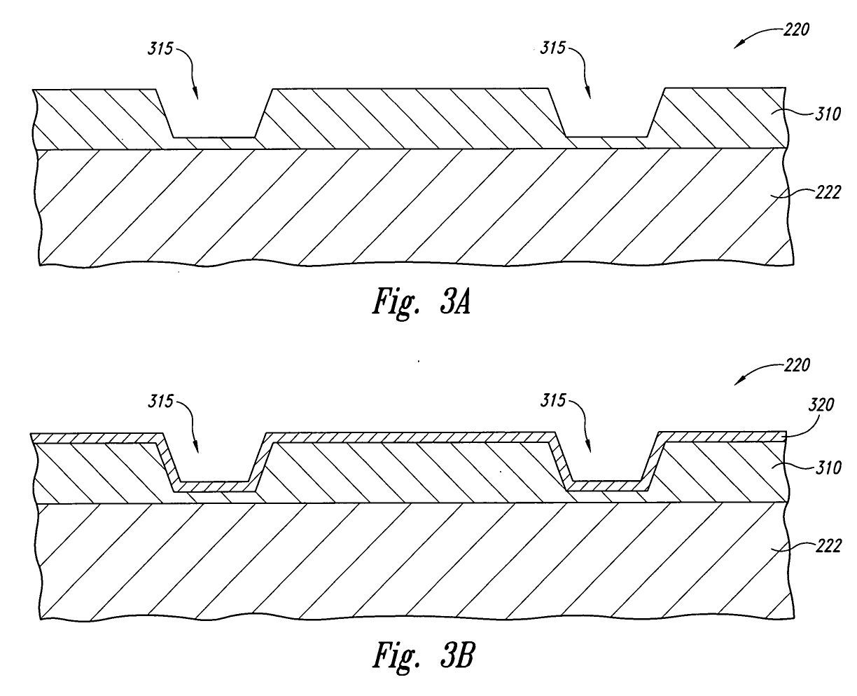

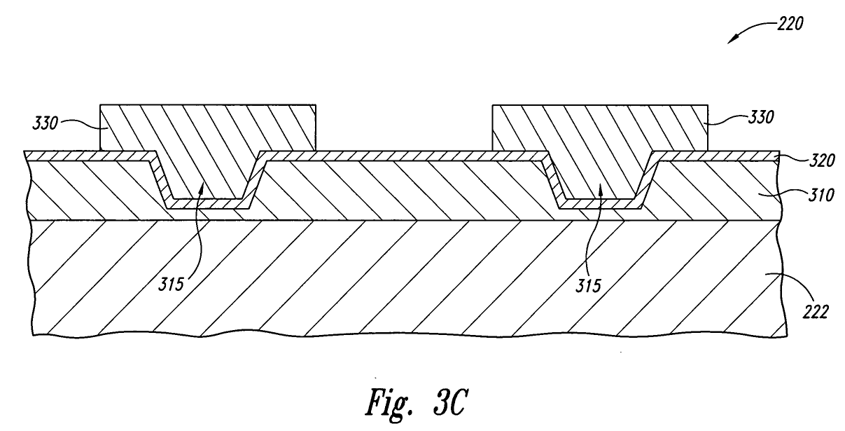

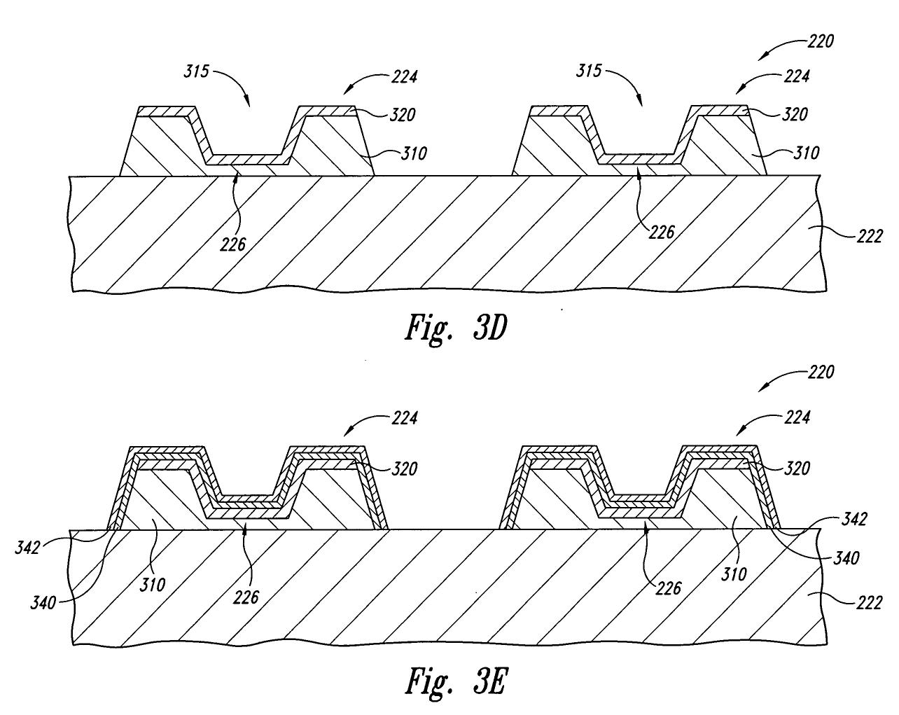

In the embodiment illustrated in FIG. 2, formation of the interconnect structures 230 and interlocking elements 232 is complete. FIGS. 3A-3E described below illustrate various embodiments of methods for forming pads having engagement features (e.g., recesses) in accordance with several embodiments of the invention. Although the following description illustrates forming only two pads, it will be appreciated that a plurality of pads are constructed simultaneously on a workpiece.

C. Methods of Forming Pads Having Engagement Features

FIGS. 3A-3E illustrate various stages in a method of forming the pads 224 (FIG. 2) in accordance with an embodiment of the invention. FIG. 3A, more specifically, is a side cross-sectional view of the workpiece 220 at an initial stage before the pads 224 (FIG. 2) have been formed. In previous processing steps, a first conductive layer 310 was deposited onto the substrate 222. The first conductive layer 310 can include Cu or other suitable materials. The first conductive layer 310 was then patterned and etched using a first etching process to form openings 315. The openings 315 are blind holes that extend at least partially through the first conductive layer 310. For purposes of this specification, a “blind hole” refers to a hole or aperture that extends only partially through a material or is otherwise closed at one end.

Referring next to FIG. 3B, a second conductive layer 320 is deposited onto the workpiece 220 and over the first conductive layer 310. The second conductive layer 320 is generally a metal layer, such as a Cu layer, that is deposited onto the first conductive layer 310 in an electroless plating operation. In other embodiments, however, the second conductive layer 320 can be composed of other suitable materials and/or be deposited onto the workpiece 220 using a different process.

After depositing the second conductive layer 320, a mask 330 is applied over the second conductive layer 320 and patterned as shown in FIG. 3C. The mask 330 can be a layer of resist or another suitable photo-active material that is patterned according to the desired arrangement of pads 224 (FIG. 2) on the substrate 222. Referring next to FIG. 3D, the first and second conductive layers 310 and 320 are etched to form pads 224 on the substrate 222. The openings 315 formed previously accordingly define the engagement features 226 in the individual pads 224. The second etching process selectively removes material from the first and second conductive layers 310 and 320, but not the substrate 222. The substrate 222 can accordingly act as an etch-stop for the second etching process.

Referring next to FIG. 3E, a third conductive layer 340 is deposited onto the workpiece 220 and over the second conductive layer 320. The third conductive layer 340 can include a Ni layer that is deposited onto the second conductive layer 320 using an electroless plating process or another suitable method. A fourth conductive layer 342 is then deposited over the third conductive layer 340. The fourth conductive layer 342 can include an Au layer that is deposited onto the third conductive layer 340 using an electroless plating process or another suitable method. In other embodiments, the third and fourth conductive layers 340 and 342 can include other materials and/or be deposited onto the workpiece 220 using other methods.

One feature of the method for forming the pads 224 described above with respect to FIGS. 3A-3E is that the size and/or shape of the openings 315 can be configured in accordance with a desired configuration of the engagement features 226 that are defined by the openings 315. An advantage of this feature is that the engagement features 226 can be customized for use within a variety of interconnect structures. For example, the size of the openings 315 (and the resulting engagement features 226) can be varied to correspond to a particular size and/or shape of stud bumps that may interconnect with the pads 224.

D. Additional Embodiments of Interconnect Structures Having Interlocking Elements

FIGS. 4A-4E illustrate several different embodiments of interconnect structures having interlocking elements to reduce and/or inhibit relative movement between the die 210 and the workpiece 220. In each of FIGS. 4A-4E, many of the features may be the same as those discussed above in connection with the assembly 200. Accordingly, like reference numbers are used to refer to like components in FIG. 2 and in FIGS. 4A-4E. The interconnect structures described below are expected to have many of the same advantages as the interconnect structures 230 described previously.

FIG. 4A is a side cross-sectional view of an interconnect structure 410 configured in accordance with an embodiment of the invention. The interconnect structure 410 can include a stud bump 414 projecting from the die 210 and engaged or otherwise mated with a pad 418 on the substrate 222 to form an interlocking element 411. The interconnect structure 410 differs from the interconnect structure 230 described above in that the pad 418 includes an engagement feature 420 having a different configuration than the engagement features 226 of the pads 224 (FIG. 2). More specifically, the engagement feature 420 of the pad 418 includes a first portion 422 having a first dimension D₁ and a second portion 424 having a second dimension D₂. The second dimension D₂ is larger than the first dimension D₁.

The engagement feature 420 of the pad 418 can be formed by over-etching the first conductive layer 310 when forming the openings 315, as described above with respect to FIG. 3A. In one aspect of this embodiment, the stud bumps 414 may need more volume than conventional stud bumps because the engagement feature 420 has a greater volume as compared with the engagement features 226 (FIG. 2). The stud bumps 414 can accordingly include “double-stacked” bumps. One advantage of the interconnect structure 410 is that the engagement feature 420 can provide additional strength to the resulting joint between the stud bump 414 and the pad 418 as compared with the interconnect structure 230 (FIG. 2) to further inhibit lateral movement between the die 210 and the workpiece 220.

FIG. 4B is a side cross-sectional view of an interconnect structure 430 configured in accordance with still another embodiment of the invention. The interconnect structure 430 can include a stud bump 432 projecting from the die 210 and engaged or otherwise mated with a pad 434 on the substrate 222 to form an interlocking element 431. The interconnect structure 430 differs from the interconnect structures described previously in that the pad 434 includes a plurality of engagement features 436, rather than just a single engagement feature. In the illustrated embodiment, for example, the engagement features 436 are relatively small openings extending to an intermediate depth in the pad 434. In other embodiments, the engagement features 436 can have a different size and/or a different arrangement on the pad 434. In several embodiments, the engagement features 436 can be formed by adjusting the concentration of the plating baths used to deposit the third and fourth conductive layers 340 and 342 onto the workpiece 220 (e.g., the concentration of the Ni and Au plating baths).

FIGS. 4C-4E are top plan views of pads having engagement features configured in accordance with still further embodiments of the invention. The following embodiments, for example, can be used when the adhesive material 235 (FIG. 2) is a non-conductive paste. Non-conductive paste, as its name implies, is a non-conductive material that can become trapped within the interconnect structure and impede the electrical connection between the stud bumps 214 on the die 210 and the pads 224 on the substrate 222 (as shown in FIG. 2). To alleviate this problem, the following embodiments include pads having “escape outlets” for the non-conductive paste such that it will not become trapped within the interconnect structures.

FIG. 4C, for example, is a top plan view of a plurality of pads 450 on the substrate 222. The pads 450 include engagement features 452 positioned to engage or otherwise mate with corresponding stud bumps on a die (not shown). The engagement features 452 in this embodiment are elongated trenches that extend across the pads 450. As such, any non-conductive paste (not shown) that becomes lodged within the engagement features 452 when attaching the die 210 to the substrate 222 can be forced out of the end portions of the trenches rather than becoming trapped within the engagement features 452.

FIG. 4D is a top plan view of a plurality of pads 460 having engagement features 462 configured in accordance with another embodiment of the invention. The pads 460 can be generally similar to the pads 450 described above with respect to FIG. 4C, except that the engagement features 462 on the pads 460 include two or more trenches extending across the pads 460. In several embodiments, the additional trenches can make it easier to align the die (not shown) with the substrate 222 because the pads 460 include multiple areas (i.e., the multiple trenches) where the stud bumps (not shown) on the die can engage the pads 460.

FIG. 4E is a top plan view of a plurality of pads 470 having engagement features 472 configured in accordance with still another embodiment of the invention. The pads 470 can be generally similar to the pads 224 described above with respect to FIG. 2. For example, the engagement features 472 on the pads 470 include a recess or opening generally similar to the recess or opening of the engagement features 226 of the pads 224. The pads 470, however, differ from the pads 224 in that the pads 470 further include outlets 474 extending from the recesses in the pads 470 to an outer edge of the pads 470. The outlets 474 can accordingly allow any non-conductive paste trapped within the recess to “escape” or otherwise exit the engagement features 472 such that the non-conductive paste does not impede or otherwise negatively affect the electrical connection between the die (not shown) and the substrate 222.

E. Additional Embodiments of Methods for Forming Pads Having Engagement Features and Microfeature Devices Including Interconnect Structures Formed Using Such Pads

FIGS. 5A-5E illustrate various stages in a method for forming pads on a microfeature workpiece in accordance with another embodiment of the invention. FIG. 5A, more specifically, is a side cross-sectional view of a workpiece 520 at an initial stage before the pads have been formed. The workpiece 520 includes a substrate 522 having a first side 524 and a second side 526 opposite the first side 524. The substrate 522 differs from the substrate 222 described above with respect to FIGS. 2 and 3A-3E in that the substrate 522 is a thin, flexible workpiece (e.g., a flexible film). In previous processing steps, a first conductive layer 530 was deposited onto the second side 526 of the substrate 522. The first conductive layer 530 can include a layer of Cu or another suitable conductive material.

Referring next to FIG. 5B, a first opening 535 is formed through the substrate 522 to expose a portion of the first conductive layer 530. More particularly, the first opening 535 is a blind hole that extends from the first side 524 of the substrate 522 completely through the substrate 522 to the first conductive layer 530. The first opening 535 can be formed using an etching process that selectively removes material from the substrate 522 without generally removing material from or otherwise negatively affecting the first conductive layer 530. In other embodiments, the first opening 535 can be formed using other suitable methods.

Referring next to FIG. 5C, a mask 538 is applied over the first side 524 of the substrate 522 and patterned to have a second opening 539 over the first opening 535. The mask 538 can be a layer of resist or another suitable photo-active material that is patterned according to a desired arrangement of pads on the substrate 522.

Referring next to FIG. 5D, a second conductive layer 550 is deposited onto the workpiece 520 in the first and second openings 535 and 539 and in contact with the first conductive layer 530. The second conductive layer 550 can include Cu that is deposited onto the workpiece 520 using an electroless plating process. In other embodiments, the second conductive layer 550 can include other suitable materials and/or be deposited using other methods.

A third conductive layer 552 is then deposited over the second conductive layer 550. The third conductive layer 552 can include a Ni layer that is deposited onto the second conductive layer 550 using an electroless plating process or another suitable method. A fourth conductive layer 554 is then deposited over the third conductive layer 552. The fourth conductive layer 554 can include an Au layer that is deposited onto the third conductive layer 552 using an electroless plating process or another suitable method. In other embodiments, the third and fourth conductive layers 552 and 554 can include other materials and/or be deposited onto the workpiece 520 using other methods.

Referring next to FIG. 5E, the mask 538 is removed from the workpiece 520 to form a plurality of pads 528 (only one is shown) on the workpiece 520. The pads 528 include engagement features 529 configured to mate or otherwise engage with corresponding engagement features on a conductive bump of a microelectronic die, as described below.

FIG. 5F is a side cross-sectional view of a microfeature device 560 configured in accordance with an embodiment of the invention. The device 560 includes the workpiece 520 having pads 528 formed using the methods described above with respect to FIGS. 5A-5E. The device 560 also includes a microelectronic die 570 having a plurality of conductive bumps 572 (e.g., stud bumps) engaged with (i.e., interlocked or otherwise mated with) corresponding pads 528 on the workpiece 520 to form interconnect structures 565 (only one is shown). The interconnect structures 565 can include many of the same advantages of the interconnect structures described above.

The device 560 can further include an adhesive material 575 disposed between the die 570 and the workpiece 520 and a redistribution structure 580 on the first conductive layer 530. The adhesive material 575 can be generally similar to the adhesive material 235 described above with respect to FIG. 2. The redistribution structure 580 can include a dielectric layer 582, a plurality of electrical couplers 584 (e.g., solder balls) for electrically coupling the device 560 to an external board or another device, and a plurality of traces 586 for electrically coupling the electrical couplers 584 to corresponding pads 528.

One feature of the device 560 is that the pads 528 extend completely through the substrate 522 to the first conductive layer 530 at the second side 526 of the substrate 522. An advantage of this feature is that the interconnect structures 565 can both (a) electrically couple the contacts on the die 570 to corresponding electrical couplers 584, and (b) reduce or inhibit relative movement between the die 570 and the workpiece 520. Conventional microfeature devices generally include vias or other features extending through a substrate or interposing structure to electrically couple pads or contacts at one side of the substrate to corresponding ball-pads at an opposite side of the substrate. The interconnect structures 565 in the device 560, however, eliminate the need for additional vias extending through the substrate 522.

From the foregoing, it will be appreciated that specific embodiments of the invention have been described herein for purposes of illustration, but that various modifications may be made without deviating from the invention. For example, the interconnect structures can include additional configurations and/or features in addition to those described above. Aspects of the invention described in the context of particular embodiments may be combined or eliminated in other embodiments. For example, any of the various configurations of interconnect structures described herein can be used with the thin film substrate described above with respect to FIGS. 5A-5F. Further, while advantages associated with certain embodiments of the invention have been described in the context of those embodiments, other embodiments may also exhibit such advantages, and not all embodiments need necessarily exhibit such advantages to fall within the scope of the invention. Accordingly, the invention is not limited except as by the appended claims.

I claim:

1. A microfeature assembly, comprising:
a microelectronic die including integrated circuitry, a plurality of terminals electrically coupled to the integrated circuitry, and conductive bumps on the individual terminals, the conductive bumps including first engagement features; and
a microfeature workpiece including a substrate and a plurality of pads on the substrate, the pads having non-planar second engagement features engaged with the first engagement features on corresponding conductive bumps.

2. The assembly of claim 1 wherein the conductive bumps include stud bumps having base portions in contact with corresponding terminals on the die and stem portions projecting from the base portions, and wherein the stem portions define the first engagement features.

3. The assembly of claim 1 wherein:
the first engagement features include protrusions; and
the non-planar second engagement features include recesses that mate with corresponding protrusions.

4. The assembly of claim 1 wherein:
the first engagement features include protrusions; and
the non-planar second engagement features include a plurality of recesses that mate with corresponding protrusions.

5. The assembly of claim 1 wherein:
the first engagement features include protrusions; and
the individual non-planar second engagement features include recesses in the pads that mate with corresponding protrusions, the second engagement features having a first portion at an exterior surface of the pad and a second portion at an intermediate depth within the pad, and wherein the first portion has a first dimension and the second portion has a second dimension greater than the first dimension.

6. The assembly of claim 1 wherein:
the first engagement features include protrusions; and
the non-planar second engagement features include elongated trenches that mate with corresponding protrusions.

7. The assembly of claim 1 wherein:
the first engagement features include protrusions; and
the individual non-planar second engagement features include a plurality of elongated trenches that mate with corresponding protrusions.

8. The assembly of claim 1 wherein:
the first engagement features include protrusions; and
the individual non-planar second engagement features include (a) a recess that mates with a corresponding protrusion, and (b) an outlet trench extending from the recess to an outer edge of the pad.

9. The assembly of claim 1 wherein the conductive bumps include uncoined stud bumps.

10. The assembly of claim 1 wherein the conductive bumps include Au conductive bumps and the pads include Au pads.

11. The assembly of claim 1, further comprising an adhesive material between the die and the workpiece.

12. The assembly of claim 11 wherein the adhesive material includes an anisotropic conductive film or a non-conductive paste.

13. The assembly of claim 1 wherein the substrate is a thin, flexible film.

14. A microfeature assembly, comprising:
a microelectronic die including integrated circuitry, a plurality of terminals electrically coupled to the integrated circuitry, and conductive bumps on the individual terminals, the conductive bumps including first interlocking elements; and
a microfeature workpiece including a substrate and a plurality of pads on the substrate, the pads having second interlocking elements mated with the first interlocking elements on corresponding conductive bumps to restrict relative movement between the die and the workpiece.

15. The assembly of claim 14 wherein the conductive bumps include stud bumps having base portions in contact with corresponding terminals on the die and stem portions projecting from the base portions, and wherein the stem portions define the first interlocking elements.

16. The assembly of claim 14 wherein:
the first interlocking elements include protrusions; and
the second interlocking elements include recesses that mate with corresponding protrusions.

17. The assembly of claim 14 wherein:
the first interlocking elements include protrusions; and
the second interlocking elements include a plurality of recesses that mate with corresponding protrusions.

18. The assembly of claim 14 wherein:
the first interlocking elements include protrusions; and
the individual second interlocking elements include recesses in the pads that mate with corresponding protrusions, the second engagement features having a first portion at an exterior surface of the pad and a second portion at an intermediate depth within the pad, and wherein the first portion has a first dimension and the second portion has a second dimension greater than the first dimension.

19. The assembly of claim 14 wherein:
the first interlocking elements include protrusions; and
the second interlocking elements include elongated trenches that mate with corresponding protrusions.

20. The assembly of claim 14 wherein:
the first interlocking elements include protrusions; and
the individual second interlocking elements include a plurality of elongated trenches that mate with corresponding protrusions.

21. The assembly of claim 14 wherein:
the first interlocking elements include protrusions; and
the individual second interlocking elements include (a) a recess that mates with a corresponding protrusion, and (b) an outlet trench extending from the recess to an outer edge of the pad.

22. The assembly of claim 14 wherein the conductive bumps include uncoined stud bumps.

23. The assembly of claim 14, further comprising an adhesive material between the die and the workpiece, wherein the adhesive material includes an anisotropic conductive film or a non-conductive paste.

24. The assembly of claim 14 wherein the substrate is a thin, flexible film.

25. A microfeature assembly, comprising:
a microelectronic die including integrated circuitry, a plurality of bond-pads electrically coupled to the integrated circuitry, and stud bumps on the individual bond-pads, the stud bumps including a base portion and a stem portion projecting away from the base portion, wherein the stem portion defines a first engagement feature; and
a microfeature workpiece including a substrate and a plurality of pads on the substrate, the pads having non-planar second engagement features engaged with corresponding first engagement features to form interconnect structures that restrict relative movement between the die and the workpiece.

26. The assembly of claim 25 wherein:
the first engagement features include protrusions; and
the non-planar second engagement features include recesses that mate with corresponding protrusions.

27. The assembly of claim 25 wherein:
the first engagement features include protrusions; and
the non-planar second engagement features include a plurality of recesses that mate with corresponding protrusions.

28. The assembly of claim 25 wherein:
the first engagement features include protrusions; and
the individual non-planar second engagement features include recesses in the pads that mate with corresponding protrusions, the second engagement features having a first portion at an exterior surface of the pad and a second portion at an intermediate depth within the pad, and wherein the first portion has a first dimension and the second portion has a second dimension greater than the first dimension.

29. The assembly of claim 25 wherein:
the first engagement features include protrusions; and
the non-planar second engagement features include elongated trenches that mate with corresponding protrusions.

30. The assembly of claim 25 wherein:
the first engagement features include protrusions; and
the individual non-planar second engagement features include a plurality of elongated trenches that mate with corresponding protrusions.

31. The assembly of claim 25 wherein:
the first engagement features include protrusions; and
the individual non-planar second engagement features include (a) a recess that mates with a corresponding protrusion, and (b) an outlet trench extending from the recess to an outer edge of the pad.

32. The assembly of claim 25, further comprising an adhesive material between the die and the workpiece, wherein the adhesive material includes an anisotropic conductive film or a non-conductive paste.

33. The assembly of claim 25 wherein the substrate is a thin, flexible film.

34. A plurality of interconnect structures between a microelectronic die and a microfeature workpiece, the die including integrated circuitry and a plurality of terminals electrically coupled to the integrated circuitry, and the workpiece including a substrate having a plurality of pads, the interconnect structures comprising:
a plurality of stud bumps on the terminals, the stud bumps including first interlocking elements; and
a plurality of non-planar second interlocking elements in the pads, wherein the non-planar second interlocking elements are mated with corresponding first interlocking elements to restrict relative movement between the die and the workpiece.

35. The interconnect structures of claim 34 wherein:
the first interlocking elements include projections; and
the non-planar second interlocking elements include recesses that mate with corresponding projections.

36. The interconnect structures of claim 34 wherein:
the first interlocking elements include projections; and
the non-planar second interlocking elements include a plurality of recesses that mate with corresponding projections.

37. The interconnect structures of claim 34 wherein:
the first interlocking elements include projections; and
the individual non-planar second interlocking elements include recesses in the pads that mate with corresponding projections, the second interlocking elements including a first portion at an exterior surface of the pad and a second portion at an intermediate depth within the pad, and wherein the first portion has a first dimension and the second portion has a second dimension greater than the first dimension.

38. The interconnect structures of claim 34 wherein:
the first interlocking elements include projections; and
the non-planar second interlocking elements include elongated trenches that mate with corresponding projections.

39. The interconnect structures of claim 34 wherein:
the first interlocking elements include projections; and
the individual non-planar second interlocking elements include a plurality of elongated trenches that mate with corresponding projections.

40. The interconnect structures of claim 34 wherein:
the first interlocking elements include projections; and
the individual non-planar second interlocking elements include (a) a recess that mates with corresponding projections, and (b) an outlet trench extending from the recess to an outer edge of the pad.

41. A microfeature assembly, comprising:
a microelectronic die including integrated circuitry, a plurality of terminals electrically coupled to the integrated circuitry, and conductive bumps on the individual terminals, the conductive bumps having first contact sections extending orthogonally relative to the die; and
a microfeature workpiece including a substrate and a plurality of pads on the substrate, the pads having second contact sections mated with the first contact sections on corresponding conductive bumps to restrict relative movement between the die and the workpiece.

42. A packaged microfeature device, comprising:
a microelectronic die including integrated circuitry and a plurality of bond-pads electrically coupled to the integrated circuitry;
a plurality of uncoined stud bumps on the bond-pads, the stud bumps including base portions and stem portions projecting from the base portions, the stem portions defining first interconnecting features;
an interposer substrate having a plurality of pads, the pads including non-planar second interconnecting features mated with corresponding first interconnecting features; and
an adhesive material between the die and the interposing structure.

43. A method of forming a microfeature assembly, the method comprising:
forming a plurality of pads having non-planar first engagement features on and/or in a microfeature workpiece; and
attaching a plurality of conductive bumps on a microelectronic die to corresponding pads on the workpiece, the die including integrated circuitry, a plurality of terminals electrically coupled to the integrated circuitry, and the conductive bumps on the terminals, the conductive bumps including second engagement features that mate with the first engagement features.

44. The method of claim 43 wherein the second engagement features include protrusions, and wherein:
forming a plurality of pads having non-planar first engagement features includes forming pads having recesses; and
attaching a plurality of conductive bumps on a microelectronic die to corresponding pads includes mating protrusions on the die with corresponding recesses.

45. The method of claim 43 wherein the second engagement features include protrusions, and wherein:
forming a plurality of pads having non-planar first engagement features includes forming pads having a plurality of recesses; and
attaching a plurality of conductive bumps on a microelectronic die to corresponding pads includes mating protrusions on the die with corresponding recesses.

46. The method of claim 43 wherein the second engagement features include protrusions, and wherein:
forming a plurality of pads having non-planar first engagement features includes forming pads having elongated trenches; and
attaching a plurality of conductive bumps on a microelectronic die to corresponding pads includes mating protrusions on the die with corresponding trenches.

47. The method of claim 43 wherein the second engagement features include protrusions, and wherein:
forming a plurality of pads having non-planar first engagement features includes forming pads having a plurality of elongated trenches; and
attaching a plurality of conductive bumps on a microelectronic die to corresponding pads includes mating protrusions on the die with corresponding trenches.

48. The method of claim 43 wherein forming a plurality of pads on a microfeature workpiece includes:
providing a substrate including a first conductive layer;
forming a plurality of first openings in the first conductive layer;
applying a second conductive layer onto the workpiece and into the openings;
depositing a layer of resist onto the workpiece and forming second openings in the resist layer over the first openings;
etching the first and second conductive layers to form a plurality of pads on the workpiece, the individual pads each including at least one of the first openings;
depositing a third conductive layer onto the second conductive layer of the individual pads; and
depositing a fourth conductive layer onto the third conductive layer.

49. The method of claim 48, further comprising removing the first conductive layer from at least a portion of the workpiece outside the first openings before depositing the second conductive layer onto the workpiece.

50. The method of claim 48, further comprising removing the layer of resist from the workpiece before depositing the third conductive layer onto the second conductive layer.

51. The method of claim 48 wherein forming a plurality of first openings in the first conductive layer includes etching a plurality of blind holes in the first conductive layer.

52. The method of claim 48 wherein forming a plurality of first openings in the first conductive layer includes forming a plurality of trenches in the first conductive layer.

53. The method of claim 48 wherein depositing a second conductive layer onto the workpiece includes depositing a layer of Cu using an electroless plating process.

54. The method of claim 48 wherein:
depositing a third conductive layer onto the second conductive layer includes depositing a layer of Ni onto the second conductive layer using an electroless plating process; and
depositing a fourth conductive layer onto the third conductive layer includes depositing a layer of Au onto the third conductive layer using an electroless plating process.

55. The method of claim 43 wherein forming a plurality of pads on a microfeature workpiece includes:
providing a thin, flexible substrate including a first side, a second side opposite the first side, and a first conductive layer on the second side, the first conductive layer including a layer of Cu;
forming a plurality of first openings in the first side of the substrate;
depositing a layer of resist onto the first side of the substrate and forming second openings in the resist layer over the first openings;
depositing a second conductive layer onto the workpiece and into the first openings in contact with the first conductive layer;
depositing a third conductive layer into the first openings and onto the second conductive layer; and
depositing a fourth conductive layer onto the third conductive layer.

56. The method of claim 55, further comprising removing the layer of resist from the workpiece after depositing the fourth conductive layer onto the third conductive layer.

57. The method of claim 55 wherein forming a plurality of first openings in the first side of the substrate includes etching a plurality of openings in the first side substrate to expose at least a portion of the first conductive layer at the second side of the substrate.

58. The method of claim 55 wherein depositing a second conductive layer onto the workpiece includes depositing a layer of Cu using an electroless plating process.

59. The method of claim 55 wherein:
depositing a third conductive layer onto the second conductive layer includes depositing a layer of Ni onto the second conductive layer using an electroless plating process; and
depositing a fourth conductive layer onto the third conductive layer includes depositing a layer of Au onto the third conductive layer using an electroless plating process.

60. The method of claim 43, further comprising disposing an adhesive material between the die and the workpiece.

61. A method of forming a microfeature assembly, the method comprising:
providing a microfeature workpiece including a substrate having a plurality of pads, the pads including non-planar first interlocking features; and
attaching a microelectronic die to the workpiece, the die including integrated circuitry, a plurality of terminals electrically coupled to the integrated circuitry, and a plurality of stud bumps on the terminals, the stud bumps including second interlocking features that mate with the first interlocking features.

62. The method of claim 61 wherein the non-planar first interlocking features include recesses and the second interlocking features include projections, and wherein:
attaching a microelectronic die to the workpiece includes mating the projections with corresponding recesses.

63. The method of claim 61 wherein the individual non-planar first interlocking features include a plurality of recesses and the second interlocking features include projections, and wherein:
attaching a microelectronic die to the workpiece includes mating the projections with the corresponding plurality of recesses.

64. The method of claim 61 wherein the non-planar first interlocking features include elongated trenches and the second interlocking features include projections, and wherein:
attaching a microelectronic die to the workpiece includes mating the projections with corresponding trenches.

65. The method of claim 61, further comprising disposing an adhesive material between the die and the workpiece.
